(19) United States
(12) Patent Application Publication
(10) Pub. No.: US 2025/0192091 A1
(43) Pub. Date: Jun. 12, 2025

(54) FAN-OUT PACKAGE STRUCTURE AND FAN-OUT PACKAGE METHOD

(71) Applicant: INSTITUTE OF SEMICONDUCTORS, GUANGDONG ACADEMY OF SCIENCES, Guangzhou (CN)

(72) Inventors: Chuan Hu, Guangzhou (CN); Yingqiang Yan, Guangzhou (CN); Xun Xiang, Guangzhou (CN)

(21) Appl. No.: 18/970,939

(22) Filed: Dec. 6, 2024

(30) Foreign Application Priority Data
Dec. 6, 2023 (CN) 202311667379.7

(51) Int. Cl. H01L 23/00; H01L 21/48; H01L 21/56; H01L 21/768; H01L 23/31; H01L 23/367; H01L 23/498

(52) U.S. Cl. CPC H01L 24/32; H01L 21/486; H01L 21/56; H01L 21/76802; H01L 21/76877; H01L 23/3128; H01L 23/3672; H01L 23/49833; H01L 23/49838; H01L 24/16; H01L 24/73; H01L 24/08; H01L 2224/08225; H01L 2224/16225; H01L 2224/32225; H01L 2224/73253; H01L 2924/37

(57) ABSTRACT

A fan-out package structure and a fan-out package method are provided. The fan-out package structure includes: a chip, an inner substrate, a bonding patch layer, an encapsulation layer, an insulation support layer, an interconnection line structure, package pins, a first electrically conductive layer and a second electrically conductive layer.

### CROSS-REFERENCE TO RELATED APPLICATION

The present disclosure claims the priority to the Chinese patent application with the filing No. 2023116673797 filed with the Chinese Patent Office on Dec. 6, 2023, and entitled “FAN-OUT PACKAGE STRUCTURE AND FAN-OUT PACKAGE METHOD”, the contents of which are incorporated herein by reference in entirety.

### TECHNICAL FIELD

The present disclosure relates to the field of memory chips, and specifically to a fan-out package structure and a fan-out package method.

### BACKGROUND ART

In a manufacturing process of an existing memory chip, a silicon through-hole and a micro copper pillar usually need to be arranged on the chip, and are fixed through a hot-pressing bonding process, which is complicated in arrangement process, too high in material cost, and expensive in hot-pressing equipment, thus leading to low production efficiency and limited performance of a product.

### SUMMARY

The present disclosure provides a fan-out package structure and a fan-out package method, which can reduce the production cost, and improve the production efficiency and performance of the product.

Embodiments of the present disclosure can be realized as follows.

Embodiments of the present disclosure provide a fan-out package structure, which includes:
a chip, an inner substrate, a bonding patch layer, an encapsulation layer, an insulation support layer, an interconnection line structure, package pins, a first electrically conductive layer and a second electrically conductive layer,
where a patch area is formed at one side of the inner substrate, the bonding patch layer and the chip are both accommodated in the patch area, the inner substrate is provided with at least one through hole, the insulation support layer is accommodated in the at least one through hole, the insulation support layer covers a surface of the inner substrate and exposes the patch area, the insulation support layer is higher than the patch area, the insulation support layer is provided with a first electrically conductive hole extending therethrough, and the first electrically conductive hole is filled therein with the first electrically conductive layer;
the chip is provided with a functional surface and a non-functional surface opposite to each other, where the functional surface is provided with at least one chip pin pad, and the bonding patch layer is in contact with both the non-functional surface and one side of the inner substrate;
the encapsulation layer is configured to encapsulate the chip, the insulation support layer and the inner substrate, the encapsulation layer is provided with a second electrically conductive hole and exposes the at least one chip pin pad and the first electrically conductive layer, the second electrically conductive hole is filled therein with the second electrically conductive layer, and the second electrically conductive layer is in electrical connection with the at least one chip pin pad and the first electrically conductive layer; and
the interconnection line structure is provided on a surface of the encapsulation layer, and the interconnection line structure is in electrical connection with both the second electrically conductive layer and the package pin.

Optionally, the patch areas are formed at two sides of the inner substrate, each of the patch areas accommodates the bonding patch layer and the chip, and two sides of the encapsulation layer are each provided with the second electrically conductive hole and the interconnection line structure.

Optionally, a thermal expansion coefficient of the inner substrate is smaller than that of the insulation support layer.

Optionally, the chip includes two sub-laminations provided opposite to each other, where the two sub-laminations are each provided with the functional surface and the non-functional surface opposite to each other, the functional surfaces of the two sub-laminations are close to each other, the non-functional surfaces of the two sub-laminations are away from each other, and the non-functional surface of one of the sub-laminations is in contact with the bonding patch layer; and
the sub-lamination away from the bonding patch layer is embedded with a third electrically conductive layer, and the third electrically conductive layer is in electrical connection with the at least one chip pin pad on the same sub-lamination.

Optionally, the chip includes at least three sub-laminations provided in the same direction, where each of the sub-laminations is provided with the functional surface and the non-functional surface opposite to each other, and the non-functional surface of one of the sub-laminations is in contact with the bonding patch layer; and
the sub-laminations not in contact with the bonding patch layer are each embedded with at least one fourth electrically conductive layer, and the fourth electrically conductive layer is in electrical connection with both the chip pin pads on two adjacent sub-laminations.

Optionally, the chip and the insulation support layer have a gap therebetween, and the encapsulation layer is filled in the gap.

Embodiments of the present disclosure further provide a fan-out package structure, which includes:
a chip, an inner substrate, a bonding patch layer, an encapsulation layer, an insulation support layer, an interconnection line structure, package pins, a first electrically conductive layer and a second electrically conductive layer,
where a patch area is formed at one side of the inner substrate, the bonding patch layer and the chip are both accommodated in the patch area, the insulation support layer covers a surface of the inner substrate and exposes the patch area, and the insulation support layer is higher than the patch area;
the chip is provided with a functional surface and a non-functional surface opposite to each other, where the functional surface is provided with at least one chip pin pad, and the bonding patch layer is in contact with both the non-functional surface and one side of the inner substrate;
the encapsulation layer is configured to encapsulate the chip, the insulation support layer and the inner substrate, the encapsulation layer is provided with a second electrically conductive hole and exposes the at least one chip pin pad, the second electrically conductive hole is filled therein with the second electrically conductive layer, and the second electrically conductive layer is in electrical connection with the at least one chip pin pad;
the interconnection line structure is provided on a surface of the encapsulation layer, and the interconnection line structure is in electrical connection with both the second electrically conductive layer and the package pins; and
the inner substrate includes two sub-heat dissipation plates and a temporary bonding layer, where the temporary bonding layer is embedded between the two sub-heat dissipation plates, and the patch area is located at one of sides of the two sub-heat dissipation plates away from each other.

Optionally, the temporary bonding layer is configured to be debonded under the action of an external force, so that the two sub-heat dissipation plates are separated from each other.

Optionally, the insulation support layer is provided with a first electrically conductive hole extending therethrough, the first electrically conductive hole is filled therein with the first electrically conductive layer, and the first electrically conductive layer is in electrical connection with the second electrically conductive layer.

Embodiments of the present disclosure further provide a fan-out package method, for fabricating the above fan-out package structure, where the fan-out package method includes:
fabricating the chip;
fabricating the inner substrate;
coating the insulation support layer on the inner substrate;
providing the first electrically conductive hole in the insulation support layer, and filling to form the first electrically conductive layer;
arranging the bonding patch layer in the patch area and mounting the chip;
coating the encapsulation layer on outer sides of the chip, the insulation support layer and the inner substrate;
providing the second electrically conductive hole in the encapsulation layer, and filling to form a second electrically conductive layer; and
arranging at least one layer of the interconnection line structure and the package pins on a surface of the encapsulation layer. Optionally, the step of fabricating the inner substrate includes:
providing the at least one through hole on the inner substrate.

Optionally, the step of coating the insulation support layer includes:
filling an insulation support material in the at least one through hole, and covering the insulation support material on a surface of the inner substrate; and
cutting off part of the insulation support material so as to keep clear of the patch area and form the insulation support layer.

Optionally, the step of fabricating the chip includes:
enabling, in a case where the chip includes two sub-laminations, the functional surfaces of the two sub-laminations to be attached to each other; and
providing a through hole extending through one of the sub-laminations and filling an electrically conductive material, so as to make the electrically conductive material be in contact with the at least one chip pin pad.

The fan-out package structure and the fan-out package method of the embodiments of the present disclosure include following beneficial effects, for example:

The fan-out package structure is fabricated by the fan-out package method, and performs electric signal transmission through various electrically conductive layers, thus reducing the number of silicon through holes provided on the chip, reducing processing difficulty, and improving production efficiency. Moreover, the chips are mounted at two sides of the inner substrate, and does not need to be fixed through hot-press bonding, so that a manufacturing cost can be reduced, heat dissipation capability can be improved, and product performance can also be improved.

### BRIEF DESCRIPTION OF DRAWINGS

In order to more clearly illustrate technical solutions of embodiments of the present disclosure, drawings which need to be used in the embodiments will be briefly introduced below. It should be understood that the drawings merely show some embodiments of the present disclosure, and thus should not be considered as limitation to the scope. Those ordinarily skilled in the art still could obtain other relevant drawings according to these drawings, without using any inventive efforts.

FIG. 1 is a structural schematic diagram of a fan-out package structure provided in embodiments of the present disclosure;

FIG. 2 is a first structural schematic diagram of a chip provided in embodiments of the present disclosure;

FIG. 3 is a second structural schematic diagram of a chip provided in embodiments of the present disclosure;

FIG. 4 is a schematic diagram of positions of through holes on an inner substrate provided in embodiments of the present disclosure;

FIG. 5 is a structural schematic diagram of the inner substrate and an insulation support layer provided in embodiments of the present disclosure;

FIG. 6 is a structural schematic diagram of the inner substrate, with a temporary bonding layer, provided in embodiments of the present disclosure;

FIG. 7 is a schematic diagram of positions of first electrically conductive layers provided in embodiments of the present disclosure;

FIG. 8 is a schematic diagram of positions of chips and bonding patch layers provided in embodiments of the present disclosure;

FIG. 9 is a structural schematic diagram, after an encapsulation layer is coated, provided in embodiments of the present disclosure;

FIG. 10 is a schematic diagram of positions of second electrically conductive layers provided in embodiments of the present disclosure; and

FIG. 11 is a schematic flowchart of a fan-out package method provided in embodiments of the present disclosure.

Reference signs: 100—fan-out package structure; 110—chip; 111—functional surface; 112—non-functional surface; 113—chip pin pad; 115—sub-lamination; 116—third electrically conductive layer; 117—fourth electrically conductive layer; 120—inner substrate; 121—patch area; 122—through hole; 125—sub-heat dissipation plate; 126—temporary bonding layer; 130—bonding patch layer; 140—encapsulation layer; 141—second electrically conductive hole; 150—insulation support layer; 151—first electrically conductive hole; 160—interconnection line structure; 170—package pins; 180—first electrically conductive layer; 190—second electrically conductive layer.

### DETAILED DESCRIPTION OF EMBODIMENTS

In order to make objectives, technical solutions and advantages of the embodiments of the present disclosure clearer, technical solutions in the embodiments of the present disclosure will be described clearly and completely below in conjunction with the drawings in the embodiments of the present disclosure. Apparently, only some but not all embodiments of the present disclosure are described. Generally, components in the embodiments of the present disclosure, as described and shown in the drawings herein, may be arranged and designed in various different configurations.

Therefore, the following detailed description of the embodiments of the present disclosure provided in the drawings is not intended to limit the scope of protection of the present disclosure, but merely represents chosen embodiments of the present disclosure. On the basis of the embodiments of the present disclosure, all of other embodiments, obtained by those ordinarily skilled in the art without using any inventive efforts, should fall within the scope of protection of the present disclosure.

It should be noted that like reference signs and letters represent like items in the following drawings, and thus, once a certain item is defined in one drawing, it is unnecessary to further define and explain the same in subsequent drawings.

In the description of the present disclosure, it should be noted that orientation or positional relationships indicated by terms such as “upper”, “lower”, “inner” and “outer”, if appear, are based on orientation or positional relationships as shown in the drawings, or orientation or positional relationships of a product of the present disclosure when being conventionally placed in use, merely for facilitating describing the present disclosure and simplifying the description, rather than indicating or implying that related devices or elements have to be in the specific orientation or configured and operated in a specific orientation; therefore, they should not be construed as limitation to the present disclosure.

Besides, the terms such as “first” and “second” are merely used for distinguishing the description, but should not be construed as indicating or implying importance in the relativity.

The terms “include”, “comprise” or any other variants thereof are intended to cover non-exclusive inclusion, so that a process, a method, an article or a device that includes a series of elements includes not only those elements, but also other elements that are not explicitly listed, or elements inherent to such process, method, article or device. Without more restrictions, an element defined with wordings “including a . . . ” does not exclude presence of other same elements in the process, method, article or device including the element.

Unless otherwise expressly specified and defined, the terms such as “provide” and “connect” shall be construed in a broad sense. For example, the term “connect” may refer to a fixed connection, a detachable connection, or an integrated connection; it may refer to a mechanical connection or an electrical connection; or it may refer to a direct connection, an indirect connection via an intermediary, or inner communication between two elements. For those ordinarily skilled in the art, specific meanings of the above terms in the present disclosure could be understood according to specific circumstances.

It should be noted that the features in the embodiments of the present disclosure may be combined with each other without conflict.

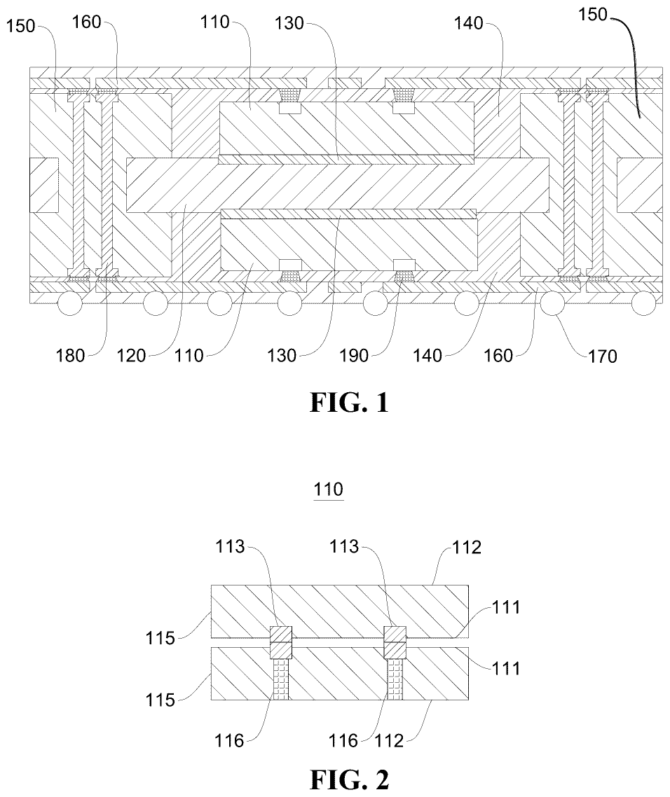

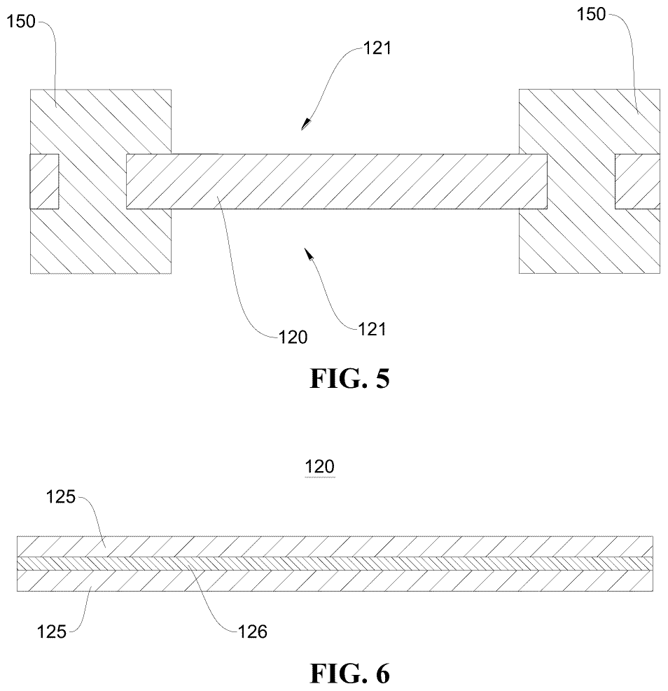

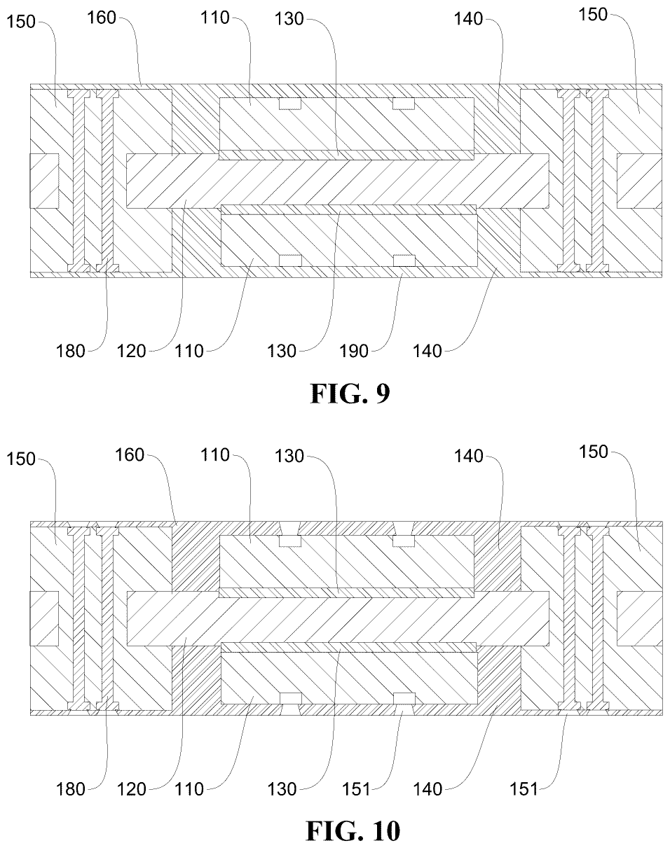

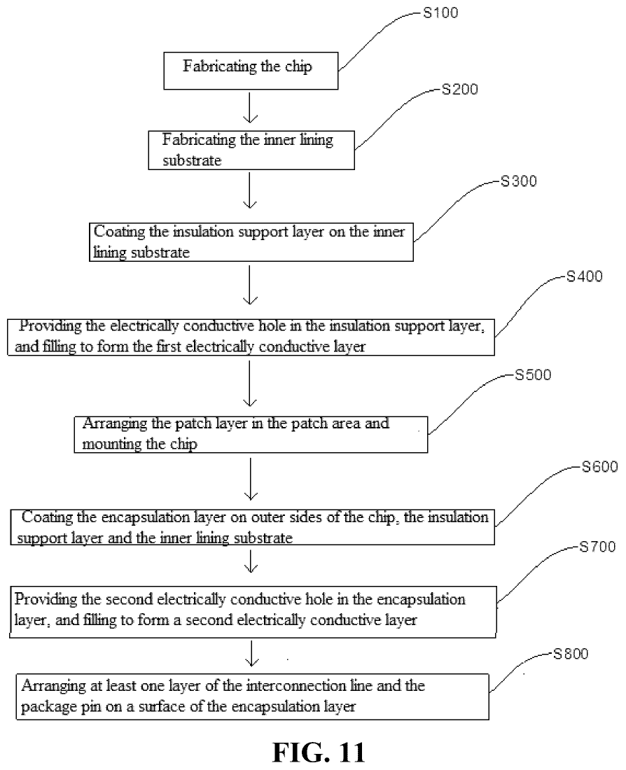

Referring to FIG. 1 to FIG. 11, a fan-out package structure 100 and a fan-out package method provided in the embodiments of the present disclosure can solve the above problem, and will be described in detail below.

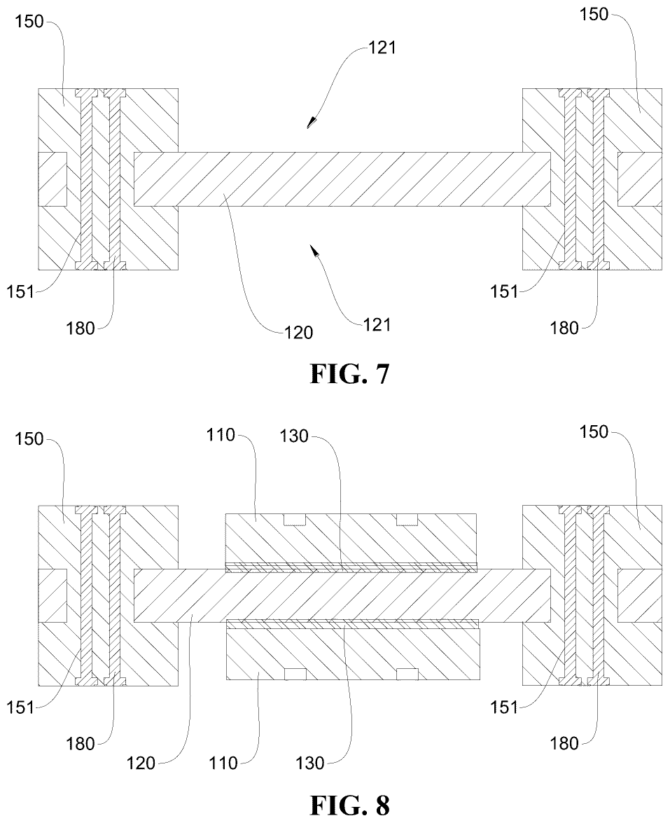

With reference to FIG. 1, FIG. 2, FIG. 7 and FIG. 10, the fan-out package structure 100 includes chips 110, an inner substrate 120, bonding patch layers 130, an encapsulation layer 140, insulation support layers 150, interconnection line structures 160, package pins 170, first electrically conductive layers 180 and second electrically conductive layers 190.

In the above, a patch area 121 is formed at one side of the inner substrate 120, and the bonding patch layer 130 and the chip 110 are both accommodated in the patch area 121. The inner substrate 120 is provided with through holes 122. The insulation support layer 150 is accommodated in the through hole 122. The insulation support layer 150 covers a surface of the inner substrate 120, and exposes the patch area 121. The insulation support layer 150 is higher than the patch area 121. The insulation support layer 150 is provided with first electrically conductive holes 151 extending therethrough, and the first electrically conductive hole 151 is filled therein with the first electrically conductive layer 180.

The chip 110 is provided with a functional surface 111 and a non-functional surface 112 opposite to each other, where the functional surface 111 is provided with chip pin pads 113, and the bonding patch layer 130 is in contact with both the non-functional surface 112 and one side of the inner substrate 120.

The encapsulation layer 140 is configured to encapsulate the chip 110, the insulation support layer 150 and the inner substrate 120. The encapsulation layer 140 is provided with a second electrically conductive hole 141, and exposes the chip pin pad 113 and the first electrically conductive layer 180. The second electrically conductive hole 141 is filled therein with the second electrically conductive layer 190. The second electrically conductive layer 190 is in electrical connection with both the chip pin pad 113 and the first electrically conductive layer 180.

The interconnection line structure 160 is provided at one side of the encapsulation layer 140, and the interconnection line structure 160 is in electrical connection with both the second electrically conductive layer 190 and the package pin 170.

The fan-out package structure 100 is fabricated by a fan-out package method, and performs electric signal transmission through various electrically conductive layers, thus reducing the number of silicon through holes provided on the chip 110, reducing processing difficulty, and improving production efficiency. Moreover, the chip 110 is mounted at two sides of the inner substrate 120, and does not need to be fixed through hot-press bonding, so that a manufacturing cost can be reduced, heat dissipation capability can be improved, and product performance can also be improved.

In the present embodiment, the patch areas 121 are formed at two sides of the inner substrate 120, each patch area 121 accommodates the bonding patch layer 130 and the chip 110; and two sides of the encapsulation layer 140 are each provided with the second electrically conductive hole 141 and the interconnection line structure 160.

It is worth noting that the thermal expansion coefficient of the inner substrate 120 is smaller than that of the insulation support layer 150.

Moreover, the inner substrate 120 and the bonding patch layer 130 are both made from thermally conductive materials, which may specifically be copper, aluminum, ceramic, alloy, or the like, so as heat dissipation can be better performed for the chip 110, and high-speed and high-bandwidth data exchange between chips 110 can be met. Definitely, the inner substrate 120 may also be made from a material such as BT resin, ABF resin, carbon fiber and graphene.

Definitely, when only a single chip 110 is needed, it is also feasible that the bonding patch layer 130 and the chip 110 are arranged only at one side of the inner substrate 120, while the encapsulation layer 140 still needs to encapsulate the insulation support layer 150 of the inner substrate 120 and the chip 110.

Referring to FIG. 2, the chip 110 may include two sub-laminations 115 provided opposite to each other, where the two sub-laminations 115 are each provided with the functional surface 111 and the non-functional surface 112 opposite to each other, the functional surfaces 111 of the two sub-laminations 115 are close to each other, the non-functional surfaces 112 of the two sub-laminations 115 are away from each other, and the non-functional surface 112 of one of the sub-laminations 115 is in contact with the bonding patch layer 130.

Specifically, the sub-lamination 115 away from the bonding patch layer 130 is embedded with third electrically conductive layers 116, and the third electrically conductive layer 116 is in electrical connection with the chip pin pad 113 on the same sub-lamination 115.

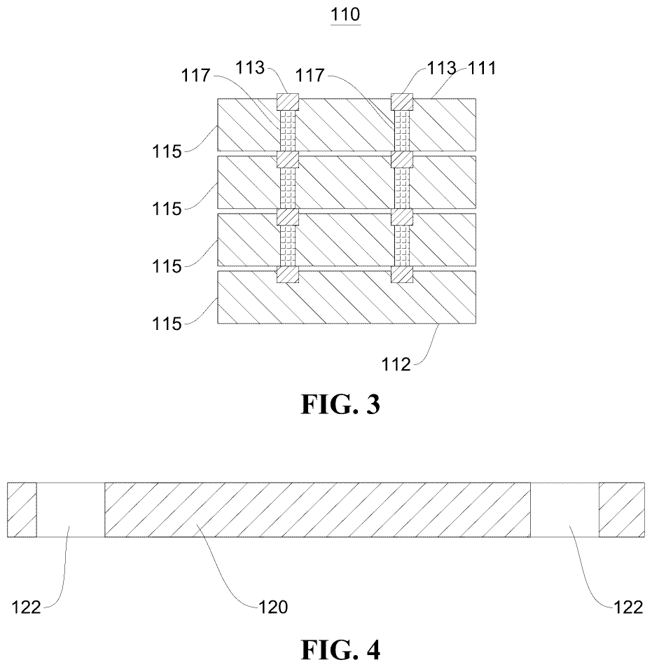

Referring to FIG. 3, the chip 110 can further include at least three sub-laminations 115 provided in the same direction, where each sub-lamination 115 is provided with the functional surface 111 and the non-functional surface 112 opposite to each other, and the non-functional surface 112 of one of the sub-laminations 115 is in contact with the bonding patch layer 130.

Specifically, the sub-laminations 115 not in contact with the bonding patch layer 130 are each embedded with fourth electrically conductive layers 117, and the fourth electrically conductive layers 117 are in electrical connection with both the chip pin pads 113 on two adjacent sub-laminations 115.

It is worth noting that the chip 110 and the insulation support layer 150 have a gap therebetween, and the encapsulation layer 140 is filled in the gap, so that the chip 110 and the insulation support layer 150 can be better spaced apart, and relative position of the two and stability of an external structure can be ensured.

It is worth noting that a specific encapsulation method of the encapsulation layer 140 includes, but is not limited to, plastic encapsulation or vacuum laminating.

Referring to FIG. 6, in a fabrication process, in order to improve fabrication efficiency, the inner substrate 120 is enabled to include two sub-heat dissipation plates 125 and a temporary bonding layer 126. The temporary bonding layer 126 is embedded between the two sub-heat dissipation plates 125. The patch area 121 is located at one of sides of the two sub-heat dissipation plates 125 away from each other. After the fabrication is completed, the temporary bonding layer 126 is enabled to be debonded under the action of an external force, so that the two sub-heat dissipation plates 125 are separated from each other, and further form two relatively small fan-out package structures 100.

It is worth noting that the inner substrate 120 having the temporary bonding layer 126 may not be provided with the through hole 122, and the insulation support layer 150 corresponding thereto may also not be provided with the first electrically conductive hole 151, so that the inner substrate 120 may be separated through debonding, thus facilitating reducing the manufacturing cost.

Definitely, the inner substrate 120 having the temporary bonding layer 126 may also be provided with the through hole 122, and the insulation support layer 150 corresponding thereto may also be provided with the first electrically conductive hole 151.

Embodiments of the present disclosure further provide a fan-out package method, for fabricating the above fan-out package structure 100. The fan-out package method includes:
S100: fabricating the chip 110, which specifically includes:
S110: enabling, in a case where the chip 110 includes two sub-laminations 115, functional surfaces 111 of the two sub-laminations 115 to be attached to each other; and
S120: providing the through hole extending through one of the sub-laminations 115 and filling an electrically conductive material, so as to make the electrically conductive material be in contact with the chip pin pad 113.

Definitely, in other embodiments of the present disclosure, the chip 110 may be of a single-layer structure or a multi-layer structure. When being of the multi-layer structure, the chip 110 includes at least three sub-laminations 115, and the at least three sub-laminations 115 are provided in the same direction.

S200: fabricating the inner substrate 120, which includes and is provided with the through hole 122, where the inner substrate 120 has a certain extension length, a direction in which the through hole 122 is provided is perpendicular to an extension direction of the inner substrate 120, and the through hole 122 may extend through two sides of the inner substrate 120.

S300: coating the insulation support layer 150 on the inner substrate 120, which specifically includes:
S310: filling an insulation support material in the through hole 122 and outside the inner substrate 120; and
S320: cutting off part of the insulation support material so as to keep clear of the patch area 121, and form an insulation support layer 150.

After the insulation support material is coated, a surface thereof needs to be polished, so that, on one hand, an external structure of the formed insulation support layer 150 is more regular, thus facilitating a subsequent encapsulation operation and arrangement of the electrically conductive layer.

S400: providing the first electrically conductive hole 151 in the insulation support layer 150, and filling the same to form the first electrically conductive layer 180.

In the present embodiment, in order to reduce material consumption and save a fabrication cost, an extension direction of the first electrically conductive hole 151 can be consistent with that of the through hole 122. Definitely, the extension directions of the two may also form a certain included angle therebetween.

S500: arranging the bonding patch layer 130 in the patch area 121 and mounting the chip 110, where the bonding patch layer 130 is formed by curing a material with certain viscosity, and has a certain heat-conducting property; and the chip 110 and the inner substrate 120 are located at two sides of the bonding patch layer 130, so that a good thermal conducting effect can also be achieved while fixing the chip 110 and the inner substrate 120, thus improving overall performance of the fan-out package structure 100.

S600: coating the encapsulation layer 140 on outer sides of the chip 110, the insulation support layer 150 and the inner substrate 120, where by coating the encapsulation layer 140, an encapsulation protection effect can be exerted on various structures inside the encapsulation layer 140, and relative position stability of various structures inside can be ensured.

S700: providing the second electrically conductive hole 141 in the encapsulation layer 140, and filling the same to form a second electrically conductive layer 190.

It is worth noting that a specific method of providing the second electrically conductive hole 141 may be exposure and development, laser drilling, dry etching, or the like, so that the second electrically conductive hole 141 can be in contact with the chip pin pad 113 of the chip 110, thus facilitating electrical connection of the filled second electrically conductive layer 190 with the chip pin pad 113.

S800: arranging at least one layer of the interconnection line structure 160 and the package pins 170 on a surface of the encapsulation layer 140, thus facilitating electrical connection of the fan-out package structure 100 with an external element.

It is worth noting that in order to protect the interconnection line structure 160, a surface of the interconnection line structure 160 may also be covered with a protection layer. In addition, the package pins 170 may also be embedded in the protection layer, which meanwhile can improve installation stability of the package pins 170.

The above-mentioned are merely specific embodiments of the present disclosure, but the scope of protection of the present disclosure is not limited thereto. Variations or substitutions, that could be readily envisaged by any technician familiar with the present technical field within the technical scope disclosed in the present disclosure, shall be covered within the scope of protection of the present disclosure. Therefore, the scope of protection of the present disclosure should be based on the scope of protection of the claims.

What is claimed is:

1. A fan-out package structure, comprising:
at least one chip, an inner substrate, at least one bonding patch layer, an encapsulation layer, at least one insulation support layer, an interconnection line structure, package pins, at least one first electrically conductive layer and a second electrically conductive layer,
wherein a patch area is formed at one side of the inner substrate, the at least one bonding patch layer and the at least one chip are both accommodated in the patch area, the inner substrate is provided with at least one through hole, the at least one insulation support layer is accommodated in the at least one through hole, the at least one insulation support layer covers a surface of the inner substrate and exposes the patch area, the at least one insulation support layer is higher than the patch area, the at least one insulation support layer is each provided with a first electrically conductive hole extending therethrough, and the first electrically conductive hole is filled therein with the first electrically conductive layer;
the at least one chip is each provided with a functional surface and a non-functional surface opposite to each other, wherein the functional surface is provided with chip pin pads, and the bonding patch layer is in contact with both the non-functional surface and one side of the inner substrate;
the encapsulation layer is configured to encapsulate the at least one chip, the at least one insulation support layer and the inner substrate, the encapsulation layer is provided with a second electrically conductive hole and exposes the chip pin pad and the first electrically conductive layer, the second electrically conductive hole is filled therein with the second electrically conductive layer, and the second electrically conductive layer is in electrical connection with the chip pin pad and the first electrically conductive layer; and
the interconnection line structure is provided on a surface of the encapsulation layer, and the interconnection line structure is in electrical connection with both the second electrically conductive layer and the package pin.

2. The fan-out package structure according to claim 1, wherein patch areas is formed at two sides of the inner substrate, each of the patch areas accommodates the corresponding bonding patch layer and the corresponding chip, and two sides of the encapsulation layer are each provided with the second electrically conductive hole and the interconnection line structure.

3. The fan-out package structure according to claim 1, wherein a thermal expansion coefficient of the inner substrate is smaller than a thermal expansion coefficient of the at least one insulation support layer.

4. The fan-out package structure according to claim 1, wherein the chip comprises two sub-laminations provided opposite to each other, wherein the two sub-laminations are each provided with the functional surface and the non-functional surface opposite to each other, the functional surfaces of the two sub-laminations are close to each other, the non-functional surfaces of the two sub-laminations are away from each other, and the non-functional surface of one of the sub-laminations is in contact with the bonding patch layer; and the sub-lamination away from the bonding patch layer is embedded with a third electrically conductive layer, and the third electrically conductive layer is in electrical connection with the chip pin pad on the same sub-lamination.

5. The fan-out package structure according to claim 1, wherein the chip comprises at least three sub-laminations provided in the same direction, wherein each of the sub-laminations is provided with the functional surface and the non-functional surface opposite to each other, and the non-functional surface of one of the sub-laminations is in contact with the bonding patch layer; and the sub-laminations not in contact with the bonding patch layer are each embedded with a fourth electrically conductive layer, and the fourth electrically conductive layer is in electrical connection with the chip pin pads on two adjacent sub-laminations.

6. The fan-out package structure according to claim 1, wherein the at least one chip and the at least one insulation support layer have a gap therebetween, and the encapsulation layer is filled in the gap.

7. A fan-out package structure, comprising:
a chip, an inner substrate, a bonding patch layer, an encapsulation layer, an insulation support layer, an interconnection line structure, package pins and a second electrically conductive layer,
wherein a patch area is formed at one side of the inner substrate, the bonding patch layer and the chip are both accommodated in the patch area, the insulation support layer covers a surface of the inner substrate and exposes the patch area, and the insulation support layer is higher than the patch area;
the chip is provided with a functional surface and a non-functional surface opposite to each other, wherein the functional surface is provided with chip pin pads, and the bonding patch layer is in contact with both the non-functional surface and one side of the inner substrate;
the encapsulation layer is configured to encapsulate the chip, the insulation support layer and the inner substrate, the encapsulation layer is provided with a second electrically conductive hole and exposes the chip pin pad, the second electrically conductive hole is filled therein with the second electrically conductive layer, and the second electrically conductive layer is in electrical connection with the chip pin pad;
the interconnection line structure is provided on a surface of the encapsulation layer, and the interconnection line structure is in electrical connection with both the second electrically conductive layer and the package pin; and
the inner substrate comprises two sub-heat dissipation plates and a temporary bonding layer, wherein the temporary bonding layer is embedded between the two sub-heat dissipation plates, and the patch area is located at one of sides of the two sub-heat dissipation plates away from each other.

8. The fan-out package structure according to claim 7, wherein the temporary bonding layer is configured to be debonded under an action of an external force, so that the two sub-heat dissipation plates are separated from each other.

9. The fan-out package structure according to claim 7, wherein the insulation support layer is provided with a first electrically conductive hole extending therethrough, the first electrically conductive hole is filled therein with the first electrically conductive layer, and the first electrically conductive layer is in electrical connection with the second electrically conductive layer.

10. A fan-out package method, for fabricating the fan-out package structure according to claim 1, wherein the fan-out package method comprises steps of:
fabricating the chip;
fabricating the inner substrate;
coating the insulation support layer on the inner substrate;
providing the first electrically conductive hole in the insulation support layer, and filling to form the first electrically conductive layer;
arranging the bonding patch layer in the patch area and mounting the chip;
coating the encapsulation layer on outer sides of the chip, the insulation support layer and the inner substrate;
providing the second electrically conductive hole in the encapsulation layer, and filling to form a second electrically conductive layer; and
arranging at least one layer of the interconnection line structure and the package pins on a surface of the encapsulation layer.

11. The fan-out package method according to claim 10, wherein the step of fabricating the inner substrate comprises:
providing the through hole on the inner substrate.

12. The fan-out package method according to claim 10, wherein the step of coating the insulation support layer comprises:
filling an insulation support material in the through hole, and covering the insulation support material on a surface of the inner substrate; and
cutting off part of the insulation support material so as to keep clear of the patch area, and form the insulation support layer.

13. The fan-out package method according to claim 10, wherein the step of fabricating the chip comprises:
enabling, in a case wherein the chip comprises two sub-laminations, the functional surfaces of the two sub-laminations to be attached to each other; and
providing a through hole extending through one of the sub-laminations and filling an electrically conductive material, so as to make the electrically conductive material be in contact with the chip pin pad.
